(19) United States
(12) Patent Application Publication
(10) Pub. No.: US 2016/0233393 A1
(43) Pub. Date: Aug. 11, 2016

(54) LIGHT EMITTING DEVICE

(71) Applicant: SHARP KABUSHIKI KAISHA, Osaka-shi, Osaka (JP)

(72) Inventors: Yohichi OKUNO, Osaka-shi (JP); Makoto TSUJI, Osaka-shi (JP); Takanobu MATSUO, Osaka-shi (JP)

(21) Appl. No.: 15/028,499

(22) PCT Filed: Sep. 19, 2014
(86) PCT No.: PCT/JP2014/074929

§ 371 Date: Apr. 11, 2016

(30) Foreign Application Priority Data
Oct. 18, 2013 (JP) 2013-217477

(51) Int. Cl. H01L 33/50; H01L 33/54; H01L 33/56; C09K 11/61; H01L 33/08

(52) U.S. Cl. CPC H01L 33/504; C09K 11/617; H01L 33/08; H01L 33/56; H01L 33/54

(57) ABSTRACT

A light-transmitting resin (21) is provided to seal LED elements (14a and 14b) disposed on a substrate (1) and a red phosphor resin (24) containing a red phosphor containing K₂SiF₆:Mn as a base material is disposed on the surface of the light-transmitting resin (21) so as to cover the LED elements (14a and 14b) and have a hemispherical shape. Therefore, variation of change with time in the emission intensity is suppressed in a light emitting layer containing a phosphor containing (Na, K)₂(Ge, Si, Ti)F₆:Mn as a base material.

### TECHNICAL FIELD

The present invention relates to a light emitting device.

### BACKGROUND ART

There is known a LED light emitting device in which light emitted from a LED element is wavelength-converted and then emitted to the outside. FIG. 12 is a cross-sectional view showing a configuration of a semiconductor light emitting device 200 disclosed in Patent Literature 1. As shown in FIG. 12, a near-ultraviolet LED element 214 is mounted on a circuit board 211. In addition, a blue/green light emitting portion 215 containing a blue phosphor and a green phosphor which are dispersed in a sealing material is formed on the surface of the circuit board 211 so as to directly cover the near-ultraviolet LED element 214. Further, a red light emitting layer 222 containing a red phosphor which is dispersed in a sealing material and is a phosphor containing a hexafluorosilicate salt as a base material is disposed on the surface of the blue/green light emitting portion 215. The blue/green light emitting portion 215 and the red light emitting layer 222 are formed to project from the circuit board 211.

### CITATION LIST

### Patent Literature

PTL 1: Japanese Unexamined Patent Application Publication No. 2010-251621 (published on Nov. 4, 2010)

### SUMMARY OF INVENTION

### Technical Problem

In the semiconductor light emitting device 2000 shown in FIG. 12, the red light emitting layer 222 containing a phosphor including a hexafluorosilicate salt as the base material is formed to linearly project in a vertical direction from the circuit board 211 and have a head portion with a curved shape. In other words, the red light emitting layer 222 is not at a constant distance from a point on the surface of the circuit board 211 (hereinafter, simply referred to as a “center” of the red light emitting layer 222) on a center axis of the red light emitting layer 222 (a center point of the red light emitting layer 222 in a plan view) perpendicular to the circuit board 211.

Therefore, the distance between the red light emitting layer 222 and the near-ultraviolet LED element 214 disposed at the center of the red light emitting layer 222 is not constant, thereby causing the problem of producing variation of a degree of change with time in emission intensity in the red light emitting layer 222 due to the light emitted from the near-ultraviolet LED element 214.

The present invention has been achieved for solving the problem described above, and an object of the invention is to suppress the occurrence of variation of change with time in emission intensity in a light emitting layer containing a phosphor containing, as a base material, a fluoride represented by (Na, K)₂(Ge, Si, Ti)F₆:Mn.

### Solution to Problem

In order to solve the problem, a light emitting device according to an embodiment of the present invention includes a substrate, a light emitting element disposed on the substrate, a sealing resin disposed on the substrate to seal the light emitting element, and a first phosphor-containing layer containing at least a red phosphor which is a phosphor containing, as a base material, a fluoride represented by (Na, K)₂(Ge, Si, Ti)F₆:Mn, the first phosphor-containing layer being disposed directly or indirectly on the surface of the sealing resin to cover the light emitting element and have a hemispherical shape.

### Advantageous Effects of Invention

According to an embodiment of the present invention, a light emitting layer containing a phosphor containing, as a base material, a fluoride represented by (Na, K)₂(Ge, Si, Ti)F₆:Mn exhibits the effect of suppressing the occurrence of variation of a change with time in emission intensity in the layer.

### BRIEF DESCRIPTION OF DRAWINGS

FIG. 1 is a sectional view showing a configuration of a LED light emitting device according to embodiment 1.

FIG. 2 is a plan view showing a configuration of a LED light emitting device according to embodiment 1.

FIG. 3 is a sectional view showing a configuration of a LED light emitting device according to a comparative example.

FIG. 4 is a diagram showing an initial emission spectrum of a LED light emitting device according to a comparative example and an emission spectrum after emission continued for about 100 hours.

FIG. 5 is a diagram showing an emission spectrum of a LED light emitting device according to the present invention after emission continued for 100 hours.

FIG. 6 is a diagram showing a relation between the emission time and chromaticity x in xy chromaticity coordinates in each of a LED light emitting device according to embodiment 1 and a LED light emitting device according to a comparative example.

FIG. 7 is a diagram showing a relation between the emission time and chromaticity y in xy chromaticity coordinates in each of a LED light emitting device according to embodiment 1 and a LED light emitting device according to a comparative example.

FIG. 8 is a diagram showing a relation between the emission time and chromaticity x in xy chromaticity coordinates in changing the drive current of a LED light emitting device according to a comparative example.

FIG. 9 is a diagram showing a relation between the emission time and chromaticity y in xy chromaticity coordinates in changing in the drive current of a LED light emitting device according to a comparative example.

FIG. 10 is a sectional view showing a configuration of a LED light emitting device according to embodiment 2.

FIG. 11 is a sectional view showing a configuration of a LED light emitting device according to embodiment 3.

FIG. 12 is a sectional view showing a configuration of a usual semiconductor light emitting device.

FIG. 13 is a sectional view showing a configuration of a LED light emitting device according to a modified example of a LED light emitting device according to embodiment 3.

### DESCRIPTION OF EMBODIMENTS

### Embodiment 1

An embodiment of the present invention is described in detail below.

### (Configuration of LED Light Emitting Device 10)

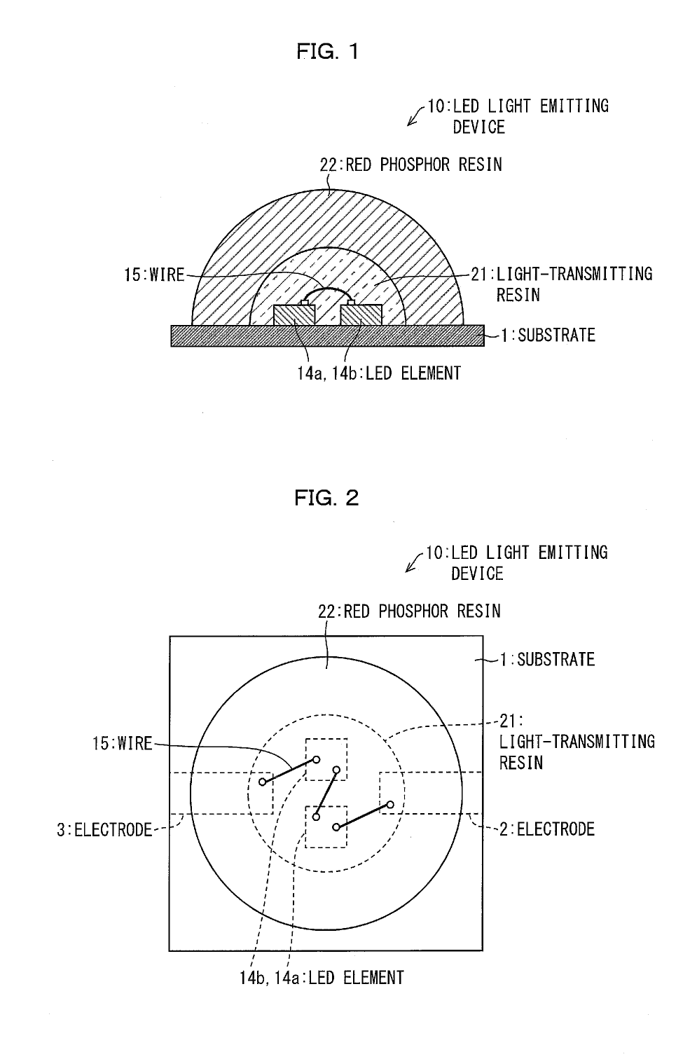

FIG. 1 is a sectional view showing a configuration of a LED light emitting device 10 according to embodiment 1. FIG. 2 is a plan view showing the configuration of the LED light emitting device 10 according to embodiment 1.

As shown in FIGS. 1 and 2, the LED light emitting device (light emitting device) 10 includes, on a substrate 1, a pair of electrodes 2 and 3, two LED elements (light emitting elements) 14a and 14b, a light-transmitting resin (sealing resin) 21 which seals the LED elements 14a and 14b, and a red phosphor resin (first phosphor-containing layer) 22 provided on the surface of the light-transmitting resin 21 to cover the light-transmitting layer 21.

The substrate 1 serves as a wiring board on which the LED elements 14a and 14b are mounted. The substrate 1 is preferably made of a material to have a high reflecting function on a main surface as a mounting surface on which the LED elements 14a and 14b are mounted. An example of the substrate 1 is a ceramic substrate.

One of the electrodes 2 and 3 is an anode electrode, and the other is a cathode electrode. The electrodes 2 and 3 serve as wiring (wiring pattern) for wire bonding of the LED elements 14a and 14b formed on the substrate 1.

The LED elements 14a and 14b are arranged between the electrode 2 and the electrode 3. The LED elements 14a and 14b are connected to each other through a wire 15 made of gold or the like, and also the LED element 14a is connected to the electrode 2, and the LED element 14b is connected to the electrode 3. Therefore, the LED elements 14a and 14b are electrically and mechanically connected to the substrate 1.

The LED elements 14a and 14b are, for example, blue LED elements which emit blue light at a peak wavelength of 450 nm. The emission color of the LED elements 14a and 14b is not limited to this, and the LED elements 14a and 14b may be ultraviolet LED elements which emit ultraviolet (near-ultraviolet) light with a peak wavelength of 390 nm to 420 nm. The emission efficiency may be improved by using the ultraviolet LED elements.

Also, the LED element 14a may be a blue LED element or ultraviolet LED element, and the LED element 14b may be a green LED element which emits green light. Therefore, white light may be realized by mixing the colors of blue light from the blue LED element, green light from the green LED element, and red light from the red phosphor.

Although the LED light emitting device 10 is described as using the two LED elements 14a and 14b in the embodiment, the number of the LED elements is not limited to 2. The LED light emitting device 10 may have only one LED element or three or more LED elements.

In addition, the LED light emitting device 10 using the LED elements 14a and 14b connected in series is described in the embodiment, but the LED elements 14a and 14b may be connected in parallel.

Further, the LED light emitting device 10 in the embodiment includes the LED elements 14a and 14b as light emitting elements, but other light emitting elements such as semiconductor lasers, organic EL elements, or the like may be used.

The light-transmitting resin 21 seals the LED elements 14a and 14b and the wires 15. For example, a silicone resin can be used as the light-transmitting resin 21. The light-transmitting resin 21 is preferably transparent but need not be necessarily transparent as long as most of the light emitted from the LED elements 14a and 14b can be transmitted. The light-transmitting resin 21 is formed on the substrate 1 so as to have a hemispherical shape. In other words, the light-transmitting resin 21 has a shape that has a constant distance (may be referred to as the “radius” of the light-transmitting resin 21 hereinafter) between the surface of the light-transmitting resin 21 (interface with the red phosphor resin 22) and a point (hereinafter, simply referred to as the “center” of the light-transmitting resin 21) on the surface of the substrate 1 and on a center axis of the light-transmitting resin 21 (a center point of the light-transmitting resin 21 in a plan view thereof) perpendicular to the substrate 1. The light-transmitting resin 21 can be formed in a hemispherical shape on the surface of the substrate 1 by, for example, applying a transparent resin such as a silicone resin or the like on the surface of the substrate 1. The radius of the light-transmitting resin 21 is about 0.1 mm or more and preferably about 0.4 mm or more.

The red phosphor resin 22 contains a red phosphor which is dispersed in a transparent resin used as a sealing material and which emits red light by the light from the LED elements 14a and 14b. For example, a silicone resin can be used as the transparent resin constituting the red phosphor resin 22. The red phosphor dispersed in the transparent resin of the red phosphor resin 22 is a phosphor containing a fluoride as a base material represented by (Na, K)₂(Ge, Si Ti)F₆:Mn. An example of the red phosphor is a phosphor (hereinafter referred to as “K₂SiF₆:Mn”) containing potassium hexafluorosilicate (K₂SiF₆) as the base material.

The inventors of the present invention found a problem of the phosphor containing K₂SiF₆:Mn that the emission intensity of the phosphor decreases with the elapse of time due to light from a LED element included and light and heat generated from the LED element.

In particular, when a drive current allowed to flow through the LED element is a high current of 200 mA or more, the emission intensity of the phosphor containing K₂SiF₆:Mn significantly changes with time, and when the drive current is 300 mA, the emission intensity of the phosphor containing K₂SiF₆:Mn particularly significantly changes with time.

The problem that the emission intensity of a phosphor that is excited by primary light emitted from a LED element and emits secondary light changes with time due to the light and heat generated from the LED element is not limited to the phosphor emitting the secondary light and containing K₂SiF₆:Mn, and the problem can be said to generally occur in phosphors containing, as a base material, a fluoride represented by (Na, K)₂(Ge, Si, Ti)F₆:Mn.

Therefore, the red phosphor resin 22 does not directly seal the LEF elements 14a and 14b and is disposed on the surface of the light-transmitting resin 21 which seals the LED elements 14a and 14b. Consequently, the red phosphor resin 22 is spaced from the LED elements 14a and 14b by a distance corresponding at least the light-transmitting resin 21 disposed thereon. Therefore, with respect to the phosphor contained in the red phosphor resin 22 and containing, as the base material, a fluoride represented by (Na, K)₂(Ge, Si, Ti)F₆:Mn, change with time in the emission intensity due to the light and heat emitted from the LED elements 14a and 14b can be suppressed.

Thus, even when the drive current allowed to flow through the LED elements 14a and 14b in order to emit light from the LED elements 14a and 14b is 200 mA or more, further about 300 mA, with respect to the phosphor containing, as the base material, a fluoride represented by (Na, K)₂(Ge, Si, Ti)F₆:Mn, change with time in the emission intensity due to the light and heat emitted from the LED elements 14a and 14b can be securely suppressed, and variation of the change with time in emission intensity can be suppressed in the red phosphor resin 22.

In particular, the red phosphor resin 22 is spaced from the LED elements 14a and 14b by about 0.1 mm or more, preferably about 0.4 mm or more. Therefore, with respect to the phosphor contained in the red phosphor resin 22 and containing, as the base material, a fluoride represented by (Na, K)₂(Ge, Si, Ti)F₆:Mn, change with time in the emission intensity due to the light and heat emitted from the LED elements 14a and 14b can be more securely suppressed.

Further, the red phosphor resin 22 is disposed on the surface of the light-transmitting resin 21 and has a shape along the surface of the light-emitting resin 21.

Specifically, the red phosphor resin 22 is formed to have a hemispherical shape together with the light-transmitting resin 21 disposed on the inner side thereof. In other words, the red phosphor resin 22 has a shape that has a constant distance (may be referred to as the “radius” of the red phosphor resin 22 hereinafter) between the surface of the red phosphor resin 22 (interface with the outside) and a point (hereinafter, may be simply referred to as the “center” of the red phosphor resin 22) on the surface of the substrate 1 and on the center axis of the red phosphor resin 22 (the center point of the red phosphor resin 22 in a plan view thereof) perpendicular to the substrate 1.

Therefore, the light and heat emitted from the LED elements 14a and 14b are substantially uniformly transmitted to the red phosphor resin 22 as compared with a shape other than the hemispherical shape. Thus, with respect to the phosphor contained in the red phosphor resin 22 and containing, as the base material, a fluoride represented by (Na, K)₂(Ge, Si, Ti)F₆:Mn, variation of change with time in the emission intensity due to the light and heat emitted from the LED elements 14a and 14b can be suppressed in the red phosphor resin 22.

In addition, the red phosphor resin 22 is described as being disposed directly on the surface of the light-transmitting resin 21, but the red phosphor resin 22 may be disposed indirectly on the surface of the light-transmitting resin 21 through another layer.

The plurality of LED elements 14a and 14b are preferably disposed in point symmetry with respect to the center of the red phosphor resin 22. This is because the light and heat emitted from the LED elements 14a and 14b can be transmitted as uniformly as possible to the red phosphor resin 22.

The red phosphor resin 22 can be formed on the surface of the substrate 1 so as to have a hemispherical shape by, for example, applying, to the surface of the substrate 1, a resin prepared by dispersing the phosphor containing, as the base material, a fluoride represented by (Na, K)₂(Ge, Si, Ti)F₆:Mn such as K₂SiF₆:Mn in a transparent resin such as a silicone resin (organic modified silicone, phenylsilicone resin, or the like).

The phosphor containing, as the base material, a fluoride represented by (Na, K)₂(Ge, Si, Ti)F₆:Mn has weak resistance to light and heat, and the red phosphor resin 22 has the necessity of being separated from the LED elements 14a and 14b because the red phosphor resin 22 uses a large amount of K₂SiF₆:Mn as an example of the red phosphor.

### EXAMPLE 1

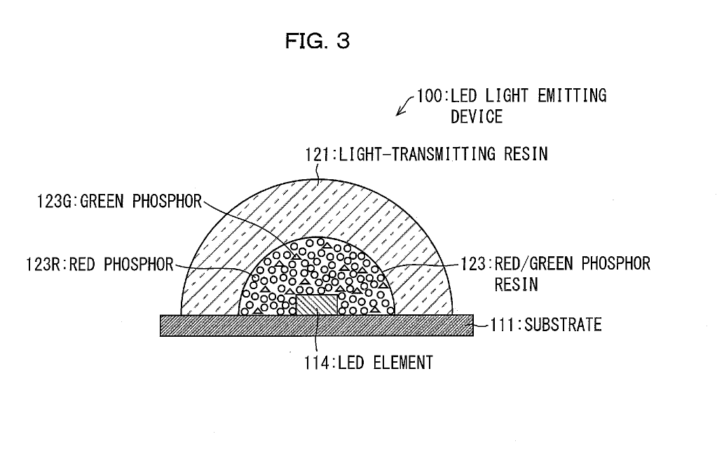

Next, Example 1 is described. An experiment was performed for comparing changes with time in emission intensity of the LED light emitting device 10 according to the embodiment and a LED light emitting device 100 according to a comparative example shown in FIG. 3. FIG. 3 is a sectional view showing a configuration of the LED light emitting device 100 according to the comparative example.

As shown in FIG. 3, the LED light emitting device 100 includes, on a substrate 111, a pair of electrodes (not shown), a LED element 114, a red/green phosphor resin 123 which seals the LED element 114, and a light-transmitting resin 121 provided on the surface of the red/green phosphor resin 123 so as to cover the red/green phosphor resin 123.

The LED element 114 emits blue light. The LED element 114 is wire-bonded to the pair of electrodes. The red/green phosphor resin 123 is disposed on the substrate 111 to directly cover the LED element 114. The red/green phosphor resin 123 contains a transparent resin in which a green phosphor 123G that emits green light by the light emitted from the LED element 114 and a red phosphor 123R that emits red light by the light emitted from the LED element 114 are dispersed. The red phosphor 123R is K₂SiF₆:Mn.

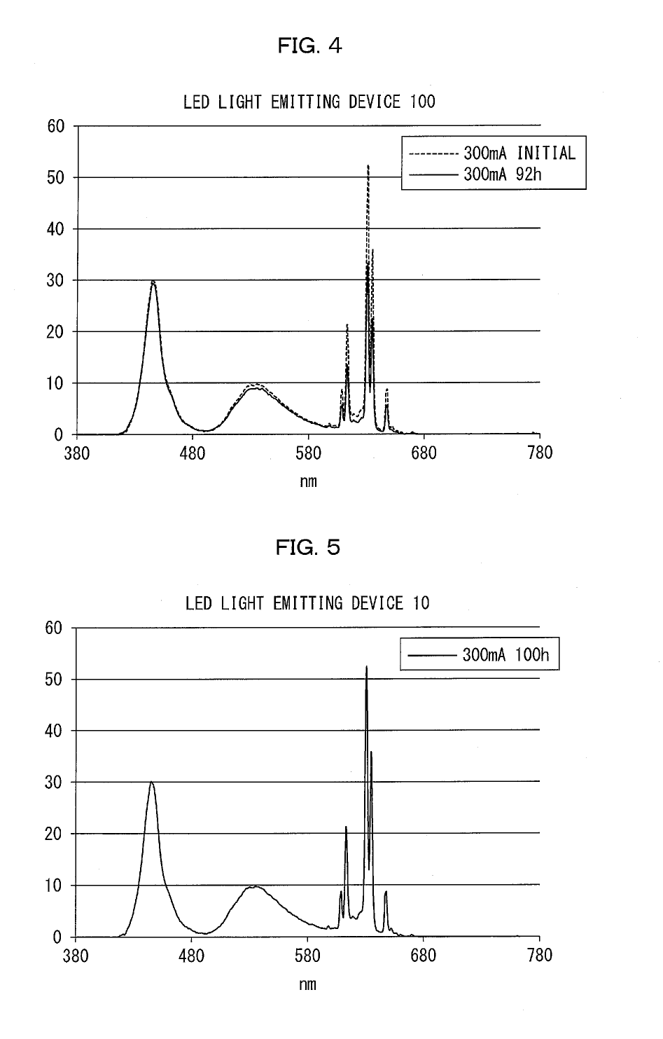

FIG. 4 is a diagram showing an initial emission spectrum of the LED light emitting device 100 according to the comparative example and an emission spectrum after emission continued for about 100 hours (92 h). The drive current allowed to flow through the LED element 114 in order to emit light from the LED light emitting device 100 was 300 mA.

FIG. 4 indicates that the red light emission intensity is decreased within a range of 600 nm to 660 nm in the emission spectrum after emission for about 100 hours as compared with the initial emission spectrum. This result indicates that the LED light emitting device 100 causes changes with time in chromaticity and emission intensity. Therefore, it is considered that K₂SiF₆:Mn is influenced by the light and heat from the LED element 114.

Then, the LED light emitting device 10 according to the embodiment shown in FIG. 1 was formed. In the LED light emitting device 10, the radius of the light-transmitting resin 21 was 0.4 mm so that the red phosphor resin 22 was spaced by about 0.4 mm from the LED elements 14a and 14b. Like in the comparison experiment of the LED light emitting device 100 according the comparative example, the drive current allowed to flow through the LED elements 14a and 14b in order to emit light from the LED light emitting device 10 was 300 mA, and light emission from the LED light emitting device 10 was performed for 100 hours.

FIG. 5 is a diagram showing an emission spectrum of the LED light emitting device 10 after emission continued for 100 hours.

FIG. 5 indicates that the emission intensity in the emission spectrum of the LED light emitting device 10 after emission for 100 hours is the same as in the initial emission spectrum of the LED light emitting device 100 according to the comparative example shown in FIG. 4. In particular, it is found that the red emission intensity is not decreased within a range of 600 nm to 660 nm.

Thus, it is found that when the red phosphor resin 22 containing K₂SiF₆:Mn is spaced by about 0.4 mm from the LED elements 14a and 14b, change with time in emission intensity in the emission spectrum, particularly within the red wavelength band in the emission spectrum, can be suppressed.

Also, the result indicates that when the red phosphor resin 22 is disposed in a hemispherical shape on the surface of the light-transmitting resin 21 and is spaced at a substantially equal distance from the LED elements 14a and 14b covered with the red phosphor resin 22, intensity variation with time of red light emitted from the red phosphor resin 22 due to the light from the LED elements 14a and 14b can be suppressed in the red phosphor resin 22.

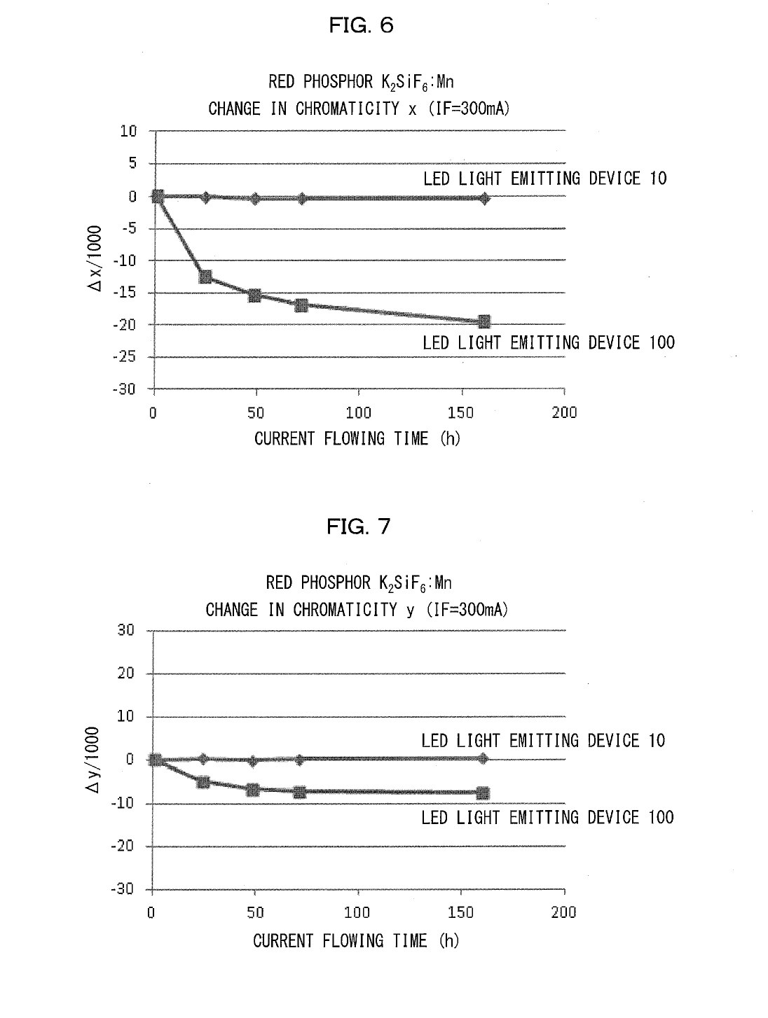

FIG. 6 is a diagram showing a relation between the emission time and chromaticity x in xy chromaticity coordinates in each of the LED light emitting devices 10 and 100. FIG. 7 is a diagram showing a relation between the emission time and chromaticity y in xy chromaticity coordinates in each of the LED light emitting devices 10 and 100. The drive currents of both the LED light emitting devices 10 and 100 are 300 mA.

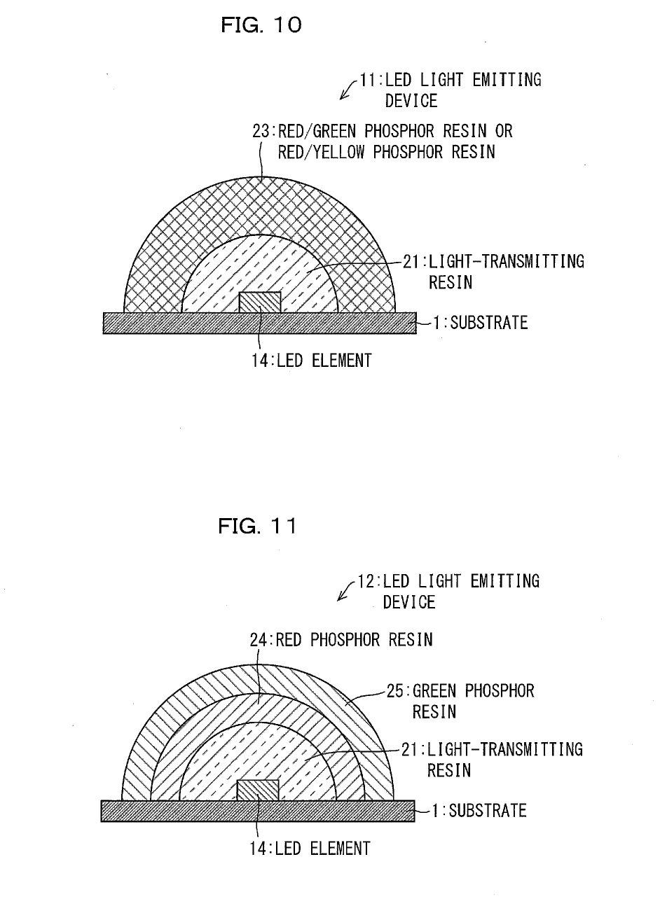

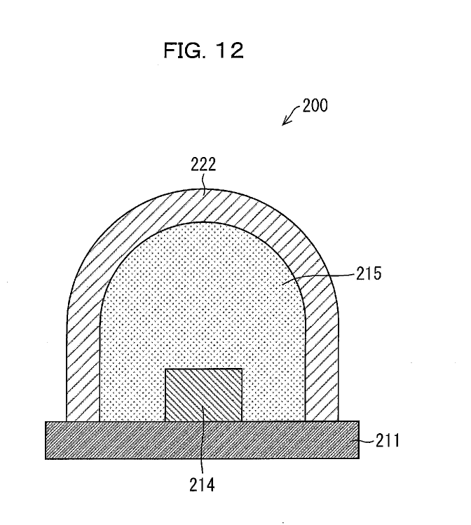

In FIGS. 6 and 7, the “current flow time” shown on the abscissa represents the emission time of each of the LED light emitting devices 10 and 100. FIGS. 6 and 7 show changes with time in chromaticity of the LED light emitting device 10 shown in FIG. 10 and the LED light emitting device 100, respectively, each using K₂SiF₆:Mn as the red phosphor.

FIGS. 6 and 7 reveal that in the LED light emitting device 100, particularly a value of x among the x and y values significantly decreases with time. On the other hand, in the LED light emitting device 10, both the values of x and y little change with time.

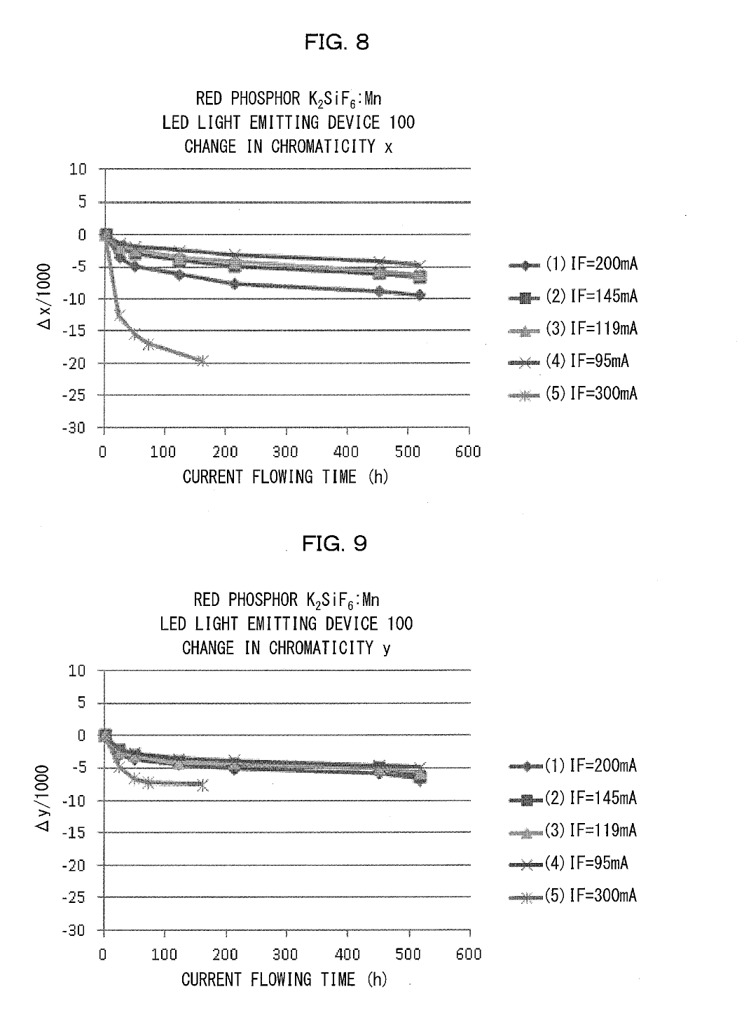

FIG. 8 is a diagram showing a relation between the emission time and chromaticity x in xy chromaticity coordinates in changing the drive current of the LED light emitting device 100. FIG. 9 is a diagram showing a relation between the emission time and chromaticity y in xy chromaticity coordinates in changing the drive current of the LED light emitting device 100. In FIGS. 8 and 9, the “current flow time” shown on the abscissa represents the emission time of the LED light emitting device 100.

FIGS. 8 and 9 reveal that when the drive current is a high current of each of (1) 200 mA and (5) 300 mA among (1) 200 mA, (2) 145 mA, (3) 119 mA, (4) 95 mA, and (5) 300 mA, the chromaticity x significantly changes with time, and particularly with (5) 300 mA, the chromaticity x greatly changes with time.

### Embodiment 2

Embodiment 2 of the present invention is described as below on the basis of FIG. 10. For convenience of description, members having the same functions as the members described in the embodiment 1 are denoted by the same reference numerals, and description thereof is omitted. An embodiment of the present invention is described in detail below.

FIG. 10 is a sectional view showing a configuration of a LED light emitting device 11 according to Embodiment 2. The LED light emitting device (light emitting device) 11 is different from the LED light emitting device 10 in that a red/green phosphor resin (first phosphor-containing layer) 23 is provided in place of the red phosphor resin 22, and a LED element (light emitting element) 14 is provided in place of the LED elements 14a and 14b. In the LED light emitting device 11, a red/yellow phosphor resin (first phosphor-containing layer) may be used in place of the red/green phosphor resin 23. The LED light emitting device 11 is the same as the LED light emitting device 10 in other components.

The LED element 14 is connected to each of a pair of electrodes (not shown) disposed on the surface of the substrate 1 through a wire (not shown). In a plan view, the LED element 14 is disposed to be located at the center of the light-transmitting resin 21 having a hemispherical shape. The LED element 14 is, for example, a blue LED element that emits blue light with a peak wavelength of 450 nm. The emission color of the LED element 14 is not limited to this, and an ultraviolet LED element that emits ultraviolet (near-ultraviolet) with a peak wavelength of 390 nm to 420 nm may be used.

The light-transmitting resin 21 is disposed on the substrate 1 so as to cover the LED element 14 and have a hemispherical shape. The radius of the light-transmitting resin 21 is about 0.1 mm or more and preferably about 0.4 mm or more.

The red/green phosphor resin 23 contains a transparent resin such as a silicone resin as a sealing material in which a phosphor used as a red phosphor and containing a fluoride as a base material represented by (Na, K)₂(Ge, Si, Ti)F₆:Mn and a green phosphor excited by blue light to emit green light are dispersed. An example of the red phosphor dispersed in the red/green phosphor resin 23 is K₂SiF₆:Mn.

When the red/yellow phosphor resin is used in place of the red/green phosphor resin 23, the red/yellow phosphor resin may contain a transparent resin such as a silicone resin as a sealing material in which a phosphor used as a red phosphor and containing a fluoride as a base material represented by (Na, K)₂(Ge, Si, Ti)F₆:Mn and a yellow phosphor excited by blue light to emit yellow light are dispersed. An example of the red phosphor dispersed in the red/yellow phosphor resin is K₂SiF₆:Mn.

Examples of the green phosphor or yellow phosphor constituting the red/green phosphor resin 23 or red/yellow phosphor resin include (Ba, Sr, Ca, Mg)₂SiO₄:Eu, (Mg, Ca, Sr, Ba)Si₂O₂N₂:Eu, (Ba, Sr)₃Si₆O₁₂N₂:Eu, Eu-activated β-Sialon, (Sr, Ca, Ba)(Al, Ga, In)₂S₄:Eu, (Y, Tb, Lu, Gd)₃(Al, Ga)₅O₁₂:Ce, Ca₃(Sc, Mg, Na, Li)₂Si₃O₁₂:Ce, (Ca, Sr)Sc₂O₄:Ce, and the like.

The red/green phosphor resin 23 is disposed on the surface of the light-transmitting resin 21 and has a shape along the surface of the light-transmitting resin 21. The red/green phosphor resin 23 is formed so as to have a hemispherical shape together with the light-transmitting resin 21 disposed inside thereof. In other words, the red/green phosphor resin 23 has a shape that has a constant distance (may be referred to as a “radius” of the red/green phosphor resin 23 hereinafter) between the surface (interface with the outside) of the red/green phosphor resin 23 and a point (hereinafter, may be simply referred to a “center of the red/green phosphor resin 23”) on the surface of the substrate 1 and on the center axis of the red/green phosphor resin 23 (center point of the red/green phosphor resin 23 in a plan view) perpendicular to the substrate 1.

Therefore, the red/green phosphor resin 23 is substantially uniformly irradiated with the light emitted from the LED element 14 as compared with a shape other than the hemispherical shape. Thus, with respect to the phosphor contained in the red/green phosphor resin 23 and containing, as the base material, a fluoride represented by (Na, K)₂(Ge, Si, Ti)F₆:Mn, variation of change with time in the emission intensity due to the light and heat emitted from the LED element 14 can be suppressed in the red/green phosphor resin 23.

Further, the red/green phosphor resin 23 is disposed to cover only one LED element 14, and the LED element 14 is disposed on the surface of the substrate 1 to be located at the center of the hemispherical red/green phosphor resin 23 in a plan view. Thus, the red/green phosphor resin 23 is more uniformly irradiated with the light emitted from the LED element 14 as compared with when a plurality of LED elements are disposed. Therefore, with respect to the phosphor contained in the red/green phosphor resin 23 and containing as the base material a fluoride represented by (Na, K)₂(Ge, Si, Ti)F₆:Mn, variation of change with time in the emission intensity due to the light emitted from the LED element 14 can be more suppressed in the red/green phosphor resin 23.

In addition, as in the red/green phosphor resin 23, when a green phosphor of a type different from the phosphor containing as the base material a fluoride represented by (Na, K)₂(Ge, Si, Ti)F₆:Mn is contained, the amount of the phosphor containing as the base material a fluoride represented by (Na, K)₂(Ge, Si, Ti)F₆:Mn can be decreased as compared with a phosphor-containing layer containing only the phosphor containing as the base material a fluoride represented by (Na, K)₂(Ge, Si, Ti)F₆:Mn. Therefore, variation of change with time in the emission intensity can be further suppressed in the red/green phosphor resin 23.

In addition, the red/green phosphor resin 23 is spaced from the LED element 14 because the re/green phosphor resin 23 does not directly seal the LED element 14 and is disposed on the surface of the light-transmitting resin 21 that seals the LED element 14. The red/green phosphor resin 23 is spaced by about 0.1 mm or more, preferably about 0.4 mm or more, from the LED element 14. Therefore, with respect to the phosphor contained in the red/green phosphor resin 23 and containing as the base material a fluoride represented by (Na, K)₂(Ge, Si, Ti)F₆:Mn, change with time in the emission intensity due to the light emitted from the LED element 14 can be more securely suppressed.

### EXAMPLE 2

A LED light emitting device 11 shown in FIG. 10 was formed and confirmed with respect to changes with time in an emission spectrum by the same method as in Example 1.

In the LED light emitting device 11, the radius of a light-transmitting resin 21 was 0.4 mm so that a red/green phosphor resin 23 was spaced by about 0.4 mm from a LED element 14. Like in Example 1, the drive current for emitting light from the LED light emitting device 11 was 300 mA, and light emission from the LED light emitting device 11 was performed for 100 hours. As a result, substantially the same emission spectrum as that shown in FIG. 5 was obtained.

It was thus found that the emission intensity in the emission spectrum of the LED light emitting device 11 after emission continued for 100 hours is the same as in the initial emission spectrum of the LED light emitting device 100 according to the comparative example shown in FIG. 4. In particular, it was found that the red emission intensity is not decreased within a range of 600 nm to 660 nm.

Thus, it was found that even in the LED light emitting device 11, when the red/green phosphor resin 23 containing K₂SiF₆:Mn is spaced by about 0.4 mm from the LED element 14, change with time in the emission intensity in the emission spectrum, particularly within the red wavelength band in the emission spectrum, can be suppressed.

Also, the result indicates that when the red/green phosphor resin 23 is disposed to have a hemispherical shape on the surface of the light-transmitting resin 21 and is spaced at a substantially equal distance from the LED element 14 covered with the red/green phosphor resin 23, intensity variation with time of red light emitted from the red/green phosphor resin 23 due to light from the LED element 14 can be suppressed in the red/green phosphor resin 23.

### Embodiment 3

Embodiment 3 of the present invention is described as below on the basis of FIG. 11. For convenience of description, members having the same functions as the members described in Embodiments 1 and 2 are denoted by the same reference numerals, and description thereof is omitted. An embodiment of the present invention is described in detail below.

FIG. 11 is a sectional view showing a configuration of a LED light emitting device 12 according to Embodiment 3. The LED light emitting device (light emitting device) 12 is different from the LED light emitting device 11 in that a red phosphor resin (first phosphor-containing layer) 24 and a green phosphor resin (second phosphor-containing layer) 25 are provided in place of the red phosphor resin 22. The LED light emitting device 12 is the same as the LED light emitting device 11 in other components.

The red phosphor resin 24 contains a transparent resin such as a silicone resin as a sealing material in which a phosphor used as a red phosphor and containing a fluoride as a base material represented by (Na, K)₂(Ge, Si, Ti)F₆:Mn is dispersed. An example of the red phosphor dispersed in the red phosphor resin 24 is K₂SiF₆:Mn. The red phosphor resin 24 is disposed on the surface of the light-transmitting resin 21 and has a shape along the surface of the light-transmitting resin 21. The red phosphor resin 24 is formed so as to have a hemispherical shape together with the light-transmitting resin 21 disposed inside thereof. In other words, the red phosphor resin 24 has a shape that has a constant distance (may be referred to as a “radius” of the red phosphor resin 24 hereinafter) between the surface (interface with the green phosphor resin 25) of the red phosphor resin 24 and a point (hereinafter, may be simply referred to a “center of the red phosphor resin 24”) on the surface of the substrate 1 and on the center axis of the red phosphor resin 24 (center point of the red phosphor resin 24 in a plan view) perpendicular to the substrate 1.

Therefore, the red phosphor resin 24 is substantially uniformly irradiated with the light emitted from the LED element 14 as compared with a shape other than the hemispherical shape. Thus, with respect to the phosphor contained in the red phosphor resin 24 and containing as the base material a fluoride represented by (Na, K)₂(Ge, Si, Ti)F₆:Mn, variation of change with time in the emission intensity due to the light and heat emitted from the LED element 14 can be suppressed in the red phosphor resin 24.

The green phosphor resin 25 contains a transparent resin such as a silicone resin as a sealing material in which the green phosphor that emits green light by the light emitted from the LED element 14 is dispersed. The green phosphor resin 25 is disposed on the surface of the red phosphor resin 24 to have a shape along the surface of the red phosphor resin 24. The green phosphor resin 25 is formed so as to have a hemispherical shape together with the light-transmitting resin 21 and the red phosphor resin 24 disposed inside thereof. In other words, the green phosphor resin 25 has a shape having a constant distance (may be referred to as a “radius” of the green phosphor resin 25 hereinafter) between the surface (interface with the outside) of the green phosphor resin 25 and a point (hereinafter, may be simply referred to a “center of the green phosphor resin 25”) on the surface of the substrate 1 and on the center axis of the green phosphor resin 25 (center point of the green phosphor resin 25 in a plan view) perpendicular to the substrate 1. The shape of the green phosphor resin 25 is not limited to the hemispherical shape and may be another shape.

Further, the red phosphor resin 24 is disposed to cover only one LED element 14, and the LED element 14 is disposed on the surface of the substrate 1 to be located at the center of the hemispherical red phosphor resin 24 in a plan view. Thus, the red phosphor resin 24 is more uniformly irradiated with the light emitted from the LED element 14 as compared with when a plurality of LED elements are disposed. Therefore, with respect to the phosphor contained in the red phosphor resin 24 and containing as the base material a fluoride represented by (Na, K)₂(Ge, Si, Ti)F₆:Mn, variation of change with time in the emission intensity due to the light emitted from the LED element 14 can be more suppressed in the red phosphor resin 24.

Also, the red phosphor resin 24 does not directly seal the LED element 14. The red phosphor resin 24 is spaced from the LED element 14 because the red phosphor resin 24 is disposed on the surface of the light-transmitting resin 21 that seals the LED element 14. Therefore, it is possible to improve the effect of suppressing change with time in emission intensity of K₂SiF₆:Mn contained in the red phosphor resin 24 due to the light emitted from the LED element 14.

The red phosphor resin 24 is spaced by about 0.1 mm or more, preferably about 0.4 mm or more, from the LED element 14. Therefore, a decrease in emission intensity of the red phosphor resin 24 can be more securely suppressed.

Also, the LED light emitting device 11 includes two phosphor-containing layers including the red phosphor resin 24 and the green phosphor resin 25 which contain different phosphors. Therefore, the thickness of the red phosphor resin 24 containing the phosphor containing, as the base material, a fluoride represented by (Na, K)₂(Ge, Si, Ti)F₆:Mn can be decreased as compared with a LED light emitting device including one red phosphor-containing layer. Therefore, with resect to the phosphor contained in the red phosphor resin 24 and containing as the base material a fluoride represented by (Na, K)₂(Ge, Si, Ti)F₆:Mn, variation of change with time in the emission intensity due to the light emitted from the LED element 14 can be more suppressed in the red phosphor resin 24 as compared with a LED light emitting device including one phosphor-containing layer.

Also, the LED light emitting device 12 has the effect of preventing scattering of the red phosphor from the red phosphor resin 24 because the red phosphor resin 24 is disposed between the light-transmitting resin 21 and the green phosphor resin 25. In addition, the supply of moisture to the red phosphor resin 24 is cut off, and thus reaction of the red phosphor with moisture can be suppressed, thereby causing the effect of suppressing the occurrence of hydrofluoric acid.

### EXAMPLE 3

A LED light emitting device 12 shown in FIG. 11 was formed and confirmed with respect to changes with time in an emission spectrum by the same method as in Examples 1 and 2.

In the LED light emitting device 12, the radius of a light-transmitting resin 21 was 0.4 mm, and further a red phosphor resin 24 was disposed on the surface of the light-transmitting resin 21. Thus, the red phosphor resin 24 was spaced by 0.4 mm or more from a LED element 14. Like in Examples 1 and 2, the drive current for emitting light from the LED light emitting device 12 was 300 mA, and light emission from the LED light emitting device 12 was performed for 100 hours. As a result, substantially the same emission spectrum as that shown in FIG. 5 could be obtained.

It was thus found that the emission intensity in the emission spectrum of the LED light emitting device 12 after emission continued for 100 hours is the same as in the initial emission spectrum of the LED light emitting device 100 according to the comparative example shown in FIG. 4. In particular, it was found that the red emission intensity is not decreased within a range of 600 nm to 660 nm.

Thus, it was found that even in the LED light emitting device 12, when the red phosphor resin 24 containing K₂SiF₆:Mn is spaced by 0.4 mm or more from the LED element 14, change with time in the emission intensity in the emission spectrum, particularly within the red wavelength band in the emission spectrum, can be suppressed.

Also, the result indicates that when the red phosphor resin 24 is disposed on the surface of the green phosphor resin 25 to have a hemispherical shape and is spaced at a substantially equal distance from the LED element 14 covered with the red phosphor resin 24, intensity variation with time of red light emitted from the red phosphor resin 24 due to the light from the LED element 14 can be suppressed in the red phosphor resin 24.

### MODIFIED EXAMPLE

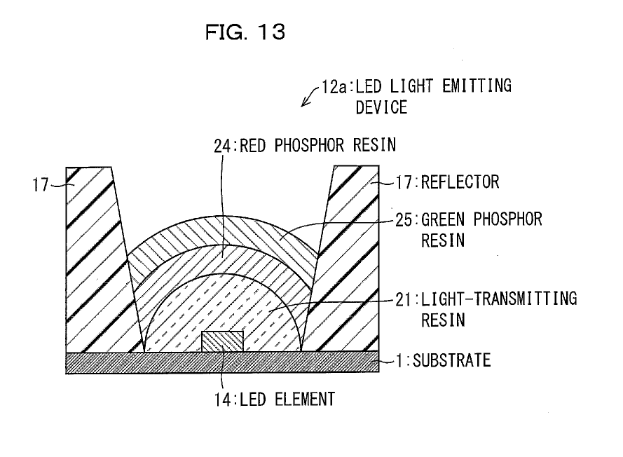

FIG. 13 is a sectional view showing a configuration of a LED light emitting device 12a according to a modified example of the LED light emitting device 12 shown in FIG. 11.

The LED light emitting device (light emitting device) 12a shown in FIG. 13 is different from the LED light emitting device 12 in that a reflector (reflecting member) 17 is provided. The LED light emitting device 12a is the same as the LED light emitting device 12 with respect to other components.

The reflector 17 is disposed on the surface of the substrate 1 to surround the LED element 14, the light-transmitting resin 21, the red phosphor resin 24, and the green phosphor resin 25.

An example of a material constituting the reflector 17 is a white resin material, but the material is not limited to this and a material generally used for the reflecting member can be used.

In the LED light emitting device (light emitting device) 12a, light emitted from the LED element 14, the red phosphor resin 24, and the green phosphor resin 25 is reflected by the reflector 17 in the direction of emission (upward direction in FIG. 13) of the LED light emitting device 12a. Therefore, light with high luminance can be emitted as compared with the LED light emitting device 12 not including the reflector 17.

### SUMMARY

A light emitting device (the LED light emitting device 10, 11, or 12) in aspect 1 of the present invention includes a substrate 1, a light emitting element (the LED element 14a, 14b, or 14) disposed on the substrate 1, a sealing resin (the light-transmitting resin 21) disposed on the substrate 1 to seal the light emitting element, and a first phosphor-containing layer (the red phosphor resin 22, 24, or the red/green phosphor resin 23) containing at least a phosphor as a red phosphor containing, as a base material, a fluoride represented by (Na, K)₂(Ge, Si, Ti)F₆:Mn, the first phosphor-containing layer being disposed directly or indirectly on the surface of the sealing resin so as to cover the light emitting element and have a hemispherical shape.

In the configuration described above, the first phosphor-containing resin is disposed directly or indirectly on the surface of the sealing resin. Therefore, the first phosphor-containing resin can be spaced from the LED element with a space corresponding to at least the sealing resin disposed thereon. Thus, change with time in the emission intensity of the red phosphor due to the light and heat emitted from the LED element can be suppressed. In addition, the first phosphor-containing layer has a hemispherical shape, and thus, variation of the change with time in the emission intensity of the red phosphor due to the light and heat emitted from the light emitting element can be suppressed in the first phosphor-containing layer.

In a light emitting device in aspect 2 of the present invention, in the aspect 1, the sealing resin has a hemispherical shape, and the radius of the sealing resin is preferably about 0.1 mm or more. In the configuration described above, change with time in the emission intensity of the red phosphor due to the light and heat emitted from the LED element can be securely suppressed.

In a light emitting device in an aspect 3 of the present invention, in the aspect 1 or 2, the first phosphor-containing resin (the red/green phosphor resin 23) preferably further contains a phosphor that emits light of a color different from the red phosphor. In the configuration, the content of the red phosphor can be decreased, variation of the change with time in the emission intensity of the red phosphor due to the light and heat emitted from the LED element 14 can be more suppressed in the first phosphor-containing layer.

In a light emitting device in aspect 4 of the present invention, in the aspects 1 to 3, a second phosphor-containing layer (the green phosphor resin 25) containing a phosphor that emits light of a color different from that of the red phosphor is provided, and the second phosphor-containing layer is preferably disposed on the surface of the first phosphor-containing layer. In the configuration, the thickness of the first phosphor-containing layer can be decreased. Thus, the content of the red phosphor can be decreased, and variation of the change with time in the emission intensity of the red phosphor due to the light and heat emitted from the LED element can be more suppressed in the first phosphor-containing layer.

In a light emitting device in aspect 5 of the present invention, in the aspects 1 to 4, the red phosphor is preferably a phosphor containing potassium hexafluorosilicate as a base material. Therefore, the red phosphor can be formed as an aspect.

In a light emitting device according to an aspect of the present invention, even in the aspects described above, the drive current allowed to flow through the light emitting element in order to emit light from the light emitting element is preferably 200 mA or more. Therefore, even when a high current is allowed to flow through the light emitting element, change with time in emission intensity of the red phosphor due to the light and heat emitted from the light emitting element and variation of the change with time in the emission intensity can be suppressed in the first phosphor-containing layer.

In a light emitting device according to an aspect of the present invention, in the aspects described above, the light-emitting element is preferably disposed to be located at the center of the first phosphor-containing layer in a plan view. In the configuration, variation of the change with time in the emission intensity of the red phosphor due to the light and heat emitted from the light emitting element can be more suppressed in the first phosphor-containing layer.

In a light emitting device according to an aspect of the present invention, in the aspects described above, the sealing resin has a hemispherical shape, and the radius of the sealing resin is preferably 0.4 mm or more. In the configuration, change with time in the emission intensity of the red phosphor can be further securely suppressed.

The present invention is not limited to the embodiments described above and various modifications can be made within the scope described in the claims. The technical scope of the present invention also includes embodiments made by properly combining the technical methods disclosed in different embodiments. Further, a new technical feature can be formed by combining the technical methods disclosed in the respective embodiments.

### INDUSTRIAL APPLICABILITY

The present invention can be used for a light emitting device.

### REFERENCE SIGNS LIST

1 SUBSTRATE

2, 3 ELECTRODE

10, 11, 12 LED LIGHT EMITTING DEVICE (LIGHT EMITTING DEVICE)

14, 14A, 14B LED ELEMENT (LIGHT EMITTING ELEMENT)

15 WIRE

21 LIGHT-TRANSMITTING RESIN (SEALING RESIN)

22 RED PHOSPHOR RESIN (FIRST PHOSPHOR-CONTAINING LAYER)

23 RED/GREEN PHOSPHOR RESIN (FIRST PHOSPHOR-CONTAINING LAYER)

24 RED PHOSPHOR RESIN (FIRST PHOSPHOR-CONTAINING LAYER)

25 GREEN PHOSPHOR RESIN (SECOND PHOSPHOR-CONTAINING LAYER)

1. A light emitting device comprising:
a substrate;
at least one light emitting element disposed on the substrate, said at least one light emitting element emitting blue light or ultraviolet;
a sealing resin disposed on the substrate to seal the light emitting element; and
a first phosphor-containing layer containing at least a red phosphor and a green phosphor, the red phosphor being a phosphor containing, as a base material, a fluoride represented by (Na, K)₂(Ge, Si, Ti)F₆:Mn, the green phosphor emitting green light,
wherein the first phosphor-containing layer is disposed directly or indirectly on the surface of the sealing resin to cover the light emitting element and have a hemispherical shape,
changes with a current flow time in chromaticity x and chromaticity y of emitted light are such that a change in the chromaticity x after 100 hours of the current flow time is 0.015 or less relative to an initial value and a change in the chromaticity y after 100 hours of the current flow time is 0.01 or less relative to an initial value.

2. The light emitting device according to claim 1, wherein the sealing resin has a hemispherical shape, and the radius of the sealing resin is 0.1 mm or more.

3. The light emitting device according to claim 1, wherein the first phosphor-containing layer further contains a phosphor that emits light of a color different from the red phosphor.

4. The light emitting device according to claim 1, further comprising a second phosphor-containing layer containing a phosphor that emits light of a color different from the red phosphor, wherein the second phosphor-containing layer is disposed on the surface of the first phosphor-containing layer.

5. The light emitting device according to claim 1, wherein the red phosphor is a phosphor containing potassium hexafluorosilicate as a base material.
